(19) United States
(12) Patent Application Publication
(10) Pub. No.: US 2002/0050835 A1
(43) Pub. Date: May 2, 2002

(54) Method and apparatus for the simultaneous electrical testing of multiple semiconductor devices

(76) Inventors: Jed Foy, West Valley City, UT (US); Cleston Messick, Sandy, UT (US); David Lotourette, Park City, UT (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/855,295

(22) Filed: May 14, 2001

Related U.S. Application Data
(60) Provisional application No. 60/244,623, filed on Oct. 30, 2000.

(51) Int. Cl. G01R 31/26

(52) U.S. Cl. 324/765

(57) ABSTRACT

A high-throughput apparatus and method for electrical testing of a plurality of semiconductor devices. The method includes electrically connecting the semiconductor devices to a common set of electrical supplies and electrical meters via a plurality of relays. Next, an electrical test (e.g., a leakage current or breakdown voltage test) is conducted on the semiconductor devices in a simultaneous manner using the common set, and a result of the electrical test is recorded. Subsequently, a determination of whether the result has a specific relationship to a predetermined value is made. If the result has the specific relationship, the semiconductor devices are organized into a first subdivision that is electrically connected to the common set via the relays and a second subdivision that is electrically disconnected from the common set using the relays. Thereafter, the electrical test is re-conducted on the first subdivision. The apparatus includes a common set of electrical supplies (e.g., a high current supply) and electrical meters, a plurality of contacts for electrically connecting the common set to the semiconductor devices and a plurality of electrical pathways for connecting the common set to the contacts. The apparatus further includes a plurality of relays disposed along the electrical pathways between the common set and the contacts. The relays enable an electrical signal from the electrical supplies to be supplied, in a selective manner, either simultaneously to the plurality of semiconductor devices or only to an individual semiconductor device.

### CROSS-REFERENCES TO RELATED APPLICATIONS

This application claims priority from co-pending U.S. Provisional Patent Application No. 60/244,623 filed Oct. 30, 2000 entitled METHOD AND APPARATUS FOR THE SIMULTANEOUS ELECTRICAL TESTING OF MULTIPLE ELECTRONIC COMPONENTS, which is hereby incorporated by reference, as if set forth in full in this document, for all purposes.

### BACKGROUND OF THE INVENTION

1. Field of the Invention

The present invention relates in general to the testing of semiconductor devices and, in particular, to methods and apparatus for the simultaneous electrical testing of multiple semiconductor devices.

2. Description of the Related Art

Automated Testing Equipment (ATE) systems and associated electrical test methods have been used since the early 1960s to individually test semiconductor devices to their electrical specifications. Conventional ATE systems include electrical supplies (e.g., current supplies and voltage supplies), electrical meters, relays, contacts and a computer-based controller. A typical ATE system-based electrical test method includes a mechanical step and an electrical step. The mechanical step physically creates an electrical connection between a single semiconductor device and the contacts, which are electrically connected to the electrical supplies and electrical meters of an ATE system via the relays. The electrical step then uses the electrical supplies and electrical meters to apply electrical signals to the single semiconductor device and to measure the resulting currents and/or voltages. A drawback of conventional ATE systems and associated electrical test methods is their low throughput, resulting from the necessity of electrically connecting and testing the individual semiconductor devices in a sequential manner.

Technological advances and reductions in the cost of relatively low power electrical supplies have enabled a “tester-on-a-pin” ATE system architecture that can electrically test multiple semiconductor devices simultaneously, thereby enhancing throughput. In a tester-on-a-pin ATE system, each semiconductor device being tested is provided with its own electrical supplies and electrical meters and, therefore, the electrical connections to each semiconductor device serve to apply current and/or voltage to the semiconductor device and to measure the resulting current and/or voltage. Such a tester-on-a-pin ATE system architecture eliminates the need for relays to electrically connect the electrical supplies and meters to the semiconductor devices. Tester-on-a-pin ATE systems and electrical test methods are, however, not suitable for the electrical testing of semiconductor devices, such as discrete semiconductors, which require the use high voltages (e.g., voltages over 10 volts) and/or high currents (e.g., currents over 100 milli-amps). The lack of suitability is due to the large and expensive nature of high voltage supplies and high current supplies.

To increase throughput by essentially reducing the time required for the mechanical step, an electrical test method referred to as “ping-pong” mode testing can be employed. Ping-pong mode testing uses separate first and second probing apparatus (i.e., first and second probers) to make electrical connections to individual semiconductor devices. The first and second probers can be selectively connected to the electrical supplies and meters of an ATE system and can move from one semiconductor device to another. When the first prober is utilizing the electrical supplies and meters to test a first semiconductor device, the second prober is moving to the next semiconductor device to be tested. When testing is complete on the first semiconductor device, the electrical supplies and meters are selectively connected to the second prober and the next semiconductor device is tested, while the first prober moves to another semiconductor device. To maximize throughput during ping-pong mode testing, testing time must be approximately equal to the time required for the probers to move from one semiconductor device to another, typically approximately 150 to 250 milliseconds. If the testing time is identical to the movement time, the electrical supplies and meters of the ATE system will be operating in an essentially continuous manner.

Conventional ATE systems and tester-on-a-pin ATE systems can be employed to conduct a variety of electrical tests. I_{GSS}, I_{DSS} and BV_{DSS} are common electrical test methods, which serve to illustrate the electrical testing (screening) of an exemplary Field Effect Transistor (FET) semiconductor device that includes a gate terminal, a source terminal, a drain terminal and a substrate.

A conventional I_{GSS} electric test method measures the leakage current through the gate terminal of a single semiconductor device. In a conventional I_{GSS} electrical test, a first predetermined voltage (usually 0V) is initially applied between the drain terminal and the source terminal of the single semiconductor device (with the substrate shorted to the source terminal) using the electrical supplies of an ATE system. A second predetermined voltage is then applied between (i.e. forced on) the gate terminal and the source terminal. After a suitable settling (i.e., stabilization) time has elapsed, the resultant current through the gate terminal is measured using the electrical meters of the ATE system. The measured current is then compared to a specified upper leakage current specification for the single semiconductor device.

A conventional I_{DSS} electric test method measures the leakage current through the drain terminal a single semiconductor device. In a conventional I_{DSS} electrical test, a first predetermined voltage (usually 0V) is initially applied between the gate terminal and the source terminal of the single semiconductor device, with the substrate shorted to the source terminal, using the electrical supplies of an ATE system. A second predetermined voltage is then applied between the source terminal and the drain terminal. After a suitable settling time has elapsed, the resultant current through the drain terminal is measured using the electrical meters of the ATE system. The measured current is then compared to a specified upper leakage current specification for the single semiconductor device.

A conventional BV_{DSS} electric test method measures the breakdown voltage (i.e., the voltage at which a specified current flow through the drain terminal of a semiconductor device) between the source terminal and the drain terminal of a single semiconductor device, with the substrate and gate terminal held at a first predetermined voltage relative to the source terminal (usually 0V). In a conventional BV_{DSS} electrical test, a first predetermined voltage (usually 0V) is applied between the gate terminal and the source terminal of a single semiconductor device, with the substrate shorted to the source terminal, using the electrical supplies of an ATE system. A known current is then forced through the drain terminal. After a suitable settling time has elapsed, the resultant voltage between the source terminal and drain terminal is measured using the electrical meters of the ATE system. The measured voltage is then compared to a specified lower limit voltage specification for a single semiconductor device.

Still needed in the field, however, is a high throughput apparatus and method for the electrical testing of semiconductor devices, including electrical testing that utilizes high current power supplies. In addition, the apparatus and method should be inexpensive and compatible with ping-pong mode testing.

### SUMMARY OF THE INVENTION

The present invention provides an inexpensive, high-throughput apparatus and method for the electrical testing of multiple (i.e., a plurality) of semiconductor devices. The apparatus and method are compatible with ping-pong mode testing and the use of high current supplies.

One exemplary embodiment of the present invention is a method that includes first electrically connecting each of a plurality of semiconductor devices (e.g., discrete semiconductor devices) to a common set of electrical supplies and electrical meters via a plurality of relays. Next, an electrical test (e.g., a leakage current or breakdown voltage electrical test) is conducted, using the common set of electrical supplies and electrical meters, on the semiconductor devices in a simultaneous manner and a result of the electrical test is recorded. A determination is then made as to whether the result of the electrical test has a specific relationship to a predetermined value. If such a relationship exists, then the semiconductor devices are organized into a first subdivision and a second subdivision. The first subdivision is electrically connected to the common set via the relays, while the second subdivision is electrically disconnected from the common set using the relays. The electrical test is subsequently re-conducted on the first subdivision of the semiconductor devices. By conducting the electrical test on a plurality of semiconductor devices in a simultaneous manner, methods according to one exemplary embodiment of the present invention provide a high throughput. In addition, the use of a common set of electrical supplies and electrical meters to test a plurality of semiconductor devices is an efficient and inexpensive use of such a set.

An exemplary apparatus for the simultaneous electrical testing of a plurality of semiconductor devices includes a common set of electrical supplies (e.g., a high current supply or high voltage supply) and electrical meters. The apparatus also includes a plurality of contacts and a plurality of electrical pathways (e.g., wires) that serve to electrically connect the common set to the plurality of semiconductor devices. The exemplary apparatus according to the present invention also includes a plurality of relays. These relays are disposed along the electrical pathways between the common set of electrical supplies and meters and the contacts. The arrangement of the contacts, relays and electrical pathways enables an electrical signal from the electrical supplies of the common set to be simultaneously supplied to one or more of the semiconductor devices in a selective manner. Since the apparatus employs only a single common set of electrical supplies and electrical meters, yet enables a simultaneous supply of an electrical to a plurality of semiconductor devices, the apparatus is inexpensive and has a high throughput.

A better understanding of the features and advantages of the present invention will be obtained by reference to the following detailed description that sets forth illustrative embodiments, in which the principles of the invention are utilized, and the accompanying drawings.

### BRIEF DESCRIPTION OF THE DRAWINGS

FIG. 1 is a flow diagram illustrating the sequence of a process according to one exemplary embodiment of the present invention; and

FIG. 2 is a schematic illustrating an apparatus, according to one exemplary embodiment of the present invention, electrically connected in parallel to a plurality of semiconductor devices.

### DETAILED DESCRIPTION OF THE INVENTION

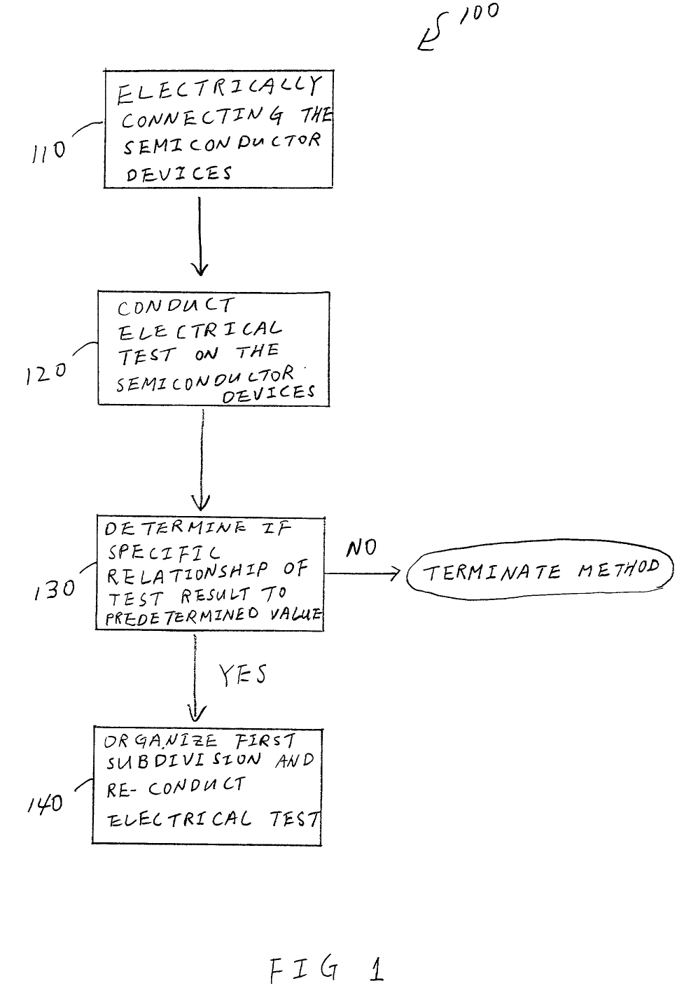

FIG. 1 is a flow diagram illustrating the sequence of steps in a process 100 for the electrical testing of a plurality of semiconductor devices in accordance with one exemplary embodiment of the present invention. Process 100 includes first electrically connecting each of the semiconductor devices to a common set of electrical supplies and electrical meters via a plurality of relays, as shown at step 110. The common set of electrical supplies and electrical meters can include, for example, high voltage supplies, high current supplies, current meters, voltage meters and any other electrical supplies and electrical meters known to one skilled in the art. The word “common” refers to the use of the set of electrical supplies and electrical meters in a shared manner in order to electrically supply and electrically meter (i.e., measure) the semiconductor devices. One skilled in the art will recognize that the common set of electrical supplies and meters can be components of an ATE system.

The plurality of semiconductor devices can be, for example, 4 semiconductor devices, 16 semiconductor devices or a greater number of semiconductor devices. The semiconductor devices can be discrete semiconductor devices (e.g., discrete Field Effect Transistor [FET] semiconductor devices) or any other type of semiconductor device known in the field. Typically, each of these semiconductor devices is electrically connected in parallel to the common set of electrical supplies and electrical meters. For Metal-Oxide-Semiconductor Field Effect Transistor (MOSFET) semiconductor devices, the electrical connections can be made, as needed, to the drain terminals, source terminals, gate terminals and substrate of the MOSFET semiconductor devices. For discrete MOS semiconductor devices, the substrate typically serves as the drain terminal and can be connected to the common set of electrical supplies and electrical meters via a relay.

Next, at step 120, an electrical test is conducted on the semiconductor devices. The electrical test is conducted in a simultaneous manner (i.e., the entire plurality of semiconductor devices are subjected to the electrical test at the same time) and using the common set of electrical supplies and electrical meters. A result of the electrical test (e.g., a voltage or a current measured using an electrical meter included in the common set) is recorded, as shown at step 120. The electrical test conducted during step 120 can be any suitable electrical test known to one skilled in the art including, for example, a leakage current electrical test or a breakdown voltage electrical test.

In a leakage current electrical test, at least one voltage signal is applied to the semiconductor devices using the electrical supplies of the common set, while the resulting leakage current is measured using the electrical meters of the common set. Typical leakage current electrical tests that can be conducted include, for example, an I_{GSS} leakage current electrical test and an I_{DSS} leakage current electrical test. In a breakdown voltage electrical test, a preset current is forced through the semiconductor devices using the electrical supplies of the common set, while the resulting voltage is measured using the electrical meters of the common set. Typical leakage current electrical tests that can be conducted include, for example, a BV_{DSS} electrical breakdown test.

Subsequently, a determination is made as to whether or not the result of the electrical test has a specific relationship to a predetermined value, as shown at step 130. For example, a determination can be made as to whether the result is greater than, less than or equal to a predetermined value. The predetermined value can be, for example, the maximum or minimum allowed test result value for an individual semiconductor device. The specific relationship, on which the determination is based, is a relationship indicating that at least one of the semiconductor devices has failed the electrical test. For example, if a leakage current electrical test is conducted, a determination is made as to whether the leakage current resulting from the electrical test is greater than a predetermined value (typically the maximum allowed leakage current for an individual semiconductor device). If the leakage current is greater than or equal to the predetermined value, it is an indication that at least one of the semiconductor devices has failed the electrical test. In that circumstance, the electrical test must be re-conducted in a manner that enables the failing semiconductor device(s) to be identified, as described below with respect to step 140. If the leakage current is less than the predetermined value, then all of the semiconductor devices are treated as having passed the electrical test and process 100 is terminated. The leakage current that results from simultaneously electrically testing the semiconductor devices can be properly compared to the maximum allowed leakage current for a single semiconductor device since the maximum allowed leakage current is typically several orders of magnitude higher than the leakage current of a passing semiconductor device.

If, on the other hand, a breakdown voltage electrical test is conducted, a determination can be made as to whether the absolute value of the breakdown voltage resulting from the electrical test is less than a predetermined value (e.g., the absolute value of the minimum allowed breakdown voltage for an individual semiconductor device). If the breakdown voltage is less than the predetermined value, then it can be concluded that at least one of the semiconductor devices has failed the electrical test. This is because a breakdown voltage electrical test conducted in a simultaneous manner on a plurality of semiconductor devices measures the lowest breakdown voltage of any of the semiconductor devices. When the breakdown voltage is less than the predetermined value, the breakdown voltage electrical test must be re-conducted in a manner that enables the failing semiconductor device(s) to be identified, as described below with respect to step 140. If the breakdown voltage is greater than the predetermined value, then all of the semiconductor devices are treated as having passed the electrical test and process 100 is terminated.

If a determination is made that the measured value has the predetermined relationship (and that, therefore, at least one of the semiconductor devices has failed the electrical test), then the semiconductor devices are organized into a first subdivision and a second subdivision, as shown at step 140. The organization is conducted such that the first subdivision of the semiconductor devices is electrically connected to the common set via the relays, while the second subdivision of the semiconductor devices is electrically disconnected from the common set using the relays. The electrical test is subsequently re-conducted on the first subdivision. If the result of re-conducting the electrical test also has the specified relationship to the predetermined value (as in step 130), then the failing semiconductor device(s) must be in the first subdivision. Otherwise, the failing device(s) must be in the second subdivision.

In a circumstance where the first subdivision includes only one semiconductor device, that semiconductor device has been effectively identified and isolated as a failing semiconductor device. Further reorganization and re-conducting of the electrical test can then be conducted, as needed, in order to isolate any failing device(s) in the second subdivision. In a circumstance where the first subdivision includes more than one semiconductor device, an iterative re-organization and re-conducting of the electrical test can serve to isolate the failing semiconductor device(s). If desired, an isolated failing semiconductor device can be excluded from any further electrical testing using the relays.

Once apprised of the present disclosure, one skilled in the art will recognize that a variety of electrical tests can be conducted using methods according to another exemplary embodiment of the present invention. For example, and I_{GSS} electrical test can be conducted on a plurality of semiconductor devices that include a source terminal, drain terminal, gate terminal and substrate. Is such an electrical test, the source terminal, drain terminal, gate terminal and substrate of each of the plurality of semiconductor devices is electrically connected to a common set of electrical supplies and electrical meters using a plurality of relays. Next, a first predetermined voltage (usually 0V) is applied between the drain terminal and the source terminal of the plurality of semiconductor devices, with the substrate shorted to the source terminal, using the electrical supplies of the common set. A second predetermined voltage is then applied between (i.e., forced on) the gate terminals and the source terminals of the plurality of semiconductor devices. After a suitable settling (i.e., stabilization) time has elapsed, the resultant leakage current through the gate terminals for the plurality of semiconductor devices is measured using the electrical meters of the common set.

The measured leakage current is subsequently compared to a specified maximum allowed leakage current for a single semiconductor device (i.e., a determination of the relationship is made). If the measured leakage current less then the specified maximum allowed leakage current, all of the semiconductor devices are considered to have passed the electrical test. If, on the other hand, the measured current is greater than the specified maximum allowed leakage current, then at least one of the semiconductor devices may have failed the electrical test. In that circumstance, the semiconductor devices are organized into a first subdivision including a single semiconductor device and a second subdivision including the remainder of the plurality of semiconductor devices. The organization is conducted such that the first subdivision (i.e., the single semiconductor device) remains electrically connected to the common set via the relays. The semiconductor devices in the second subdivision are, however, electrically disconnected from the common set using the relays. Subsequently, the electrical test is re-conducted on the first subdivision. The re-organization and re-conducting of the electrical test can then be repeated, as needed, until each of the semiconductor devices has been individually tested. The failing semiconductor device(s), if any, is thereby identified and isolated.

Based on this disclosure, one skilled in the art can easily foresee that the method according to the exemplary embodiment of the present invention can also be utilized to conduct an I_{DSS} or BV_{DSS} electrical test on a plurality of semiconductor devices.

Methods according to the present invention have a high throughput since a plurality of semiconductor devices can be electrically tested in the same time period as one semiconductor device could be tested using conventional methods. The method is inexpensive since only a single common set of electrical supplies and electrical meters is used to conduct the electrical test on the semiconductor devices. For electrical tests that require expensive and large high current electrical supplies, the cost savings will be especially pronounced. Furthermore, the method is compatible with ping-pong mode testing.

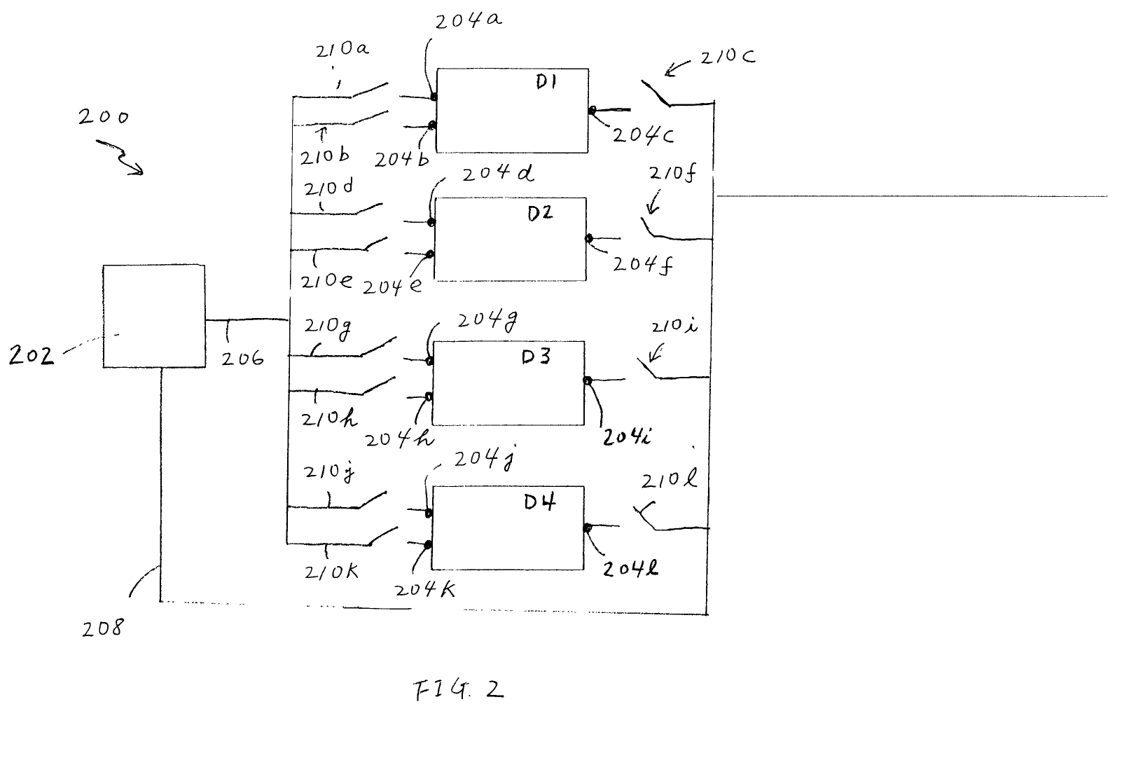

FIG. 2 is a schematic illustrating an apparatus 200, for the simultaneous electrical testing of a plurality of semiconductor devices (D1, D2, D3 and D4), according to an exemplary embodiment of the present invention. Apparatus 200 includes a common set of electrical supplies and electrical meters 202. Common set 202 of can include, for example, a high voltage supply and a current meter and/or a high current supply and a voltage meter. Common set 202 can be a component of an automated tester, such as an Automated Test Equipment (ATE) system. Apparatus 200 also includes a plurality of contacts 204a-2041 configured for electrically connecting common set 202 to semiconductor devices D1, D2, D3 and D4. Contacts 204a-2041 can be configured to provide an electrical connection to, for example, a drain terminal, source terminal, gate terminal and/or substrate of semiconductor devices D1-D4. Furthermore, the drain terminal can be a substrate-drain terminal of a discrete semiconductor device. Apparatus 200 further includes a plurality of electrical pathways 206 and 208 (e.g., cables, wires or other suitable electrical signal carrying devices) for connecting common set 202 to contacts 204a-2041.

A plurality of relays 210a-2101, disposed along the electrical pathways 206 and 208 between common set 202 and contacts 204a-2041, is also included in apparatus 200. Relays 210a-2101 are essentially switches that can be instructed (e.g., via a computer-based controller) to open and, thus, electrically disconnect a contact from common set 202, or to close, and thus electrically connect a contact to common set 202. Relays 210a-2101 can be implemented using, for example, a relay board or other relay hardware known to one skilled in the art.

Contacts 204a-2041, relays 210a-2101 and electrical pathways 206, 208 are configured for an electrical signal (e.g., an applied voltage or applied current) to be simultaneously supplied to semiconductor devices D1-D4 using the electrical supplies of common set 202. Relays 210a-2101 also enable an electrical signal to be supplied individually (i.e., separately) to each of the individual semiconductor devices.

The configuration of apparatus 200 enables the simultaneous electrical testing of the semiconductor devices (e.g., discrete field effect transistor devices) using the common set of electrical supplies and meters 202. In the embodiment of FIG. 2, relays are disposed on each electrical pathway 206, 208 between common set 202 and each of the contacts 204a-2041 of each of the semiconductor devices. Such a configuration provides for voltages and currents to be supplied to the contacts associated with each semiconductor device separately or simultaneously depending on the manner in which the relays are opened and closed.

Since apparatus 200 can be used to test a plurality of semiconductor devices simultaneously, the apparatus has a high throughput. In addition, since apparatus 200 employs a common set of electrical supplies and electrical meters, the number of expensive high current power supplies is kept to a minimum.

It should be understood that various alternatives to the embodiments of the invention described herein may be employed in practicing the invention. It is intended that the following claims define the scope of the invention and that methods and structures within the scope of these claims and their equivalents be covered thereby.

What is claimed is:

1. A method for electrically testing a plurality of semiconductor devices comprising:
electrically connecting each of the semiconductor devices to a common set of electrical supplies and electrical meters via a plurality of relays;
conducting an electrical test on the semiconductor devices in a simultaneous manner using the common set and recording a result of the electrical test;
determining whether the result of the electrical test has a specific relationship to a predetermined value; and
organizing, when the result of the electrical test has the specific relationship to the predetermined value, the semiconductor devices into a first subdivision and a second subdivision, the first subdivision electrically connected to the common set via the relays and the second subdivision electrically disconnected from the common set using the relays, and subsequently re-conducting the electrical test on the first subdivision.

2. The method of claim 1 further comprising, during the conducting step, conducting a leakage current electrical test and recording the leakage current through the semiconductor devices; and
during the determining step, determining whether an absolute value of the recorded leakage current is greater than the predetermined value.

3. The method of claim 2, wherein the predetermined value is a maximum allowed leakage current for an individual semiconductor device of the semiconductor devices.

4. The method of claim 2 further comprising, during the conducting step, conducting an I_{GSS} leakage current electrical test.

5. The method of claim 2 further comprising, during the conducting step, conducting an I_{DSS} leakage current electrical test.

6. The method of claim 1 further comprising, during the conducting step, conducting a breakdown voltage electrical test and recording a resultant voltage when a preset current is forced through the semiconductor devices; and
during the determining step, determining whether an absolute value of the recorded resultant voltage is less than the predetermined value.

7. The method of claim 6 further comprising, during the conducting step, conducting a BV_{DSS} breakdown voltage electrical test.

8. The method of claim 6, wherein the predetermined value is the absolute value of a minimum allowed breakdown voltage for an individual semiconductor device of the semiconductor devices.

9. The method of claim 1, further comprising, during the electrically connecting step, electrically connecting each of the semiconductor devices to a common set of electrical supplies and electrical meters in parallel via the relays.

10. The method of claim 1, wherein the plurality of the semiconductor devices include at least 4 semiconductor devices.

11. The method of claim 1, wherein the plurality of the semiconductor devices include at least 16 semiconductor devices.

12. The method of claim 1, wherein the plurality of semiconductor devices is a plurality of discrete semiconductor devices.

13. The method of claim 1 further comprising, during the organizing step, organizing the semiconductor devices into a first subdivision including only one semiconductor device.

14. An apparatus for simultaneous electrical testing of a plurality of semiconductor devices, the apparatus comprising:
a common set of electrical supplies and electrical meters;
a plurality of contacts for electrically connecting the common set of electrical supplies and electrical meters to the semiconductor devices;
a plurality of electrical pathways for connecting the common set of electrical supplies and meters to the contacts; and
a plurality of relays disposed along the electrical pathways between the common set of electrical supplies and electrical meters and the contacts;
wherein the contacts, the relays and the electrical pathways are configured for an electrical signal from the electrical supplies of the common set to be selectively and simultaneously supplied to the semiconductor devices and for an electrical signal to be selectively and individually supplied to each of the semiconductor devices.

15. The apparatus of claim 14, wherein the common set of electrical supplies and electrical meters includes a high voltage supply and a current meter.

16. The apparatus of claim 14, wherein the common set of electrical supplies and electrical meters includes a high current supply and a voltage meter.

17. The apparatus of claim 14, wherein the common set of electrical supplies and meters is a component of an automated tester.
